(19) United States
(12) Patent Application Publication
(10) Pub. No.: US 2025/0132215 A1
(43) Pub. Date: Apr. 24, 2025

(54) SEMICONDUCTOR DEVICE

(71) Applicant: XIAMEN SAN'AN INTEGRATED CIRCUIT CO., LTD., Xiamen (CN)

(72) Inventors: Jiebin ZHONG, Xiamen (CN); Qipeng HUANG, Xiamen (CN)

(21) Appl. No.: 18/745,382

(22) Filed: Jun. 17, 2024

Related U.S. Application Data
(63) Continuation-in-part of application No. PCT/CN2023/125520, filed on Oct. 20, 2023.

(51) Int. Cl. H01L 23/31; H01L 21/56; H01L 23/29; H01L 29/20

(52) U.S. Cl. CPC H01L 23/3171; H01L 21/56; H01L 23/291; H10D 62/8503

(57) ABSTRACT

A semiconductor device including an epitaxial structure, a first passivation layer, a second passivation layer and a gate structure is prepared. The first passivation layer is disposed on the epitaxial structure and has a through hole and a recess that spatially communicates with the through hole. The through hole extends from a top surface of the first passivation layer to a bottom surface of the first passivation layer, and the recess is spaced apart from the epitaxial structure. The second passivation layer is disposed in the recess. The gate structure passes through the through hole and is connected to the epitaxial structure. The first passivation layer has a side surface that borders the recess and that is a curved surface.

### CROSS-REFERENCE TO RELATED APPLICATION

This application is a continuation-in-part (CIP) of International Application No. PCT/CN2023/125520, filed on Oct. 20, 2023, the entire disclosure of which is incorporated by reference herein.

### FIELD

The disclosure relates to a semiconductor device and a method for preparing the semiconductor device.

### BACKGROUND

A GaN-based high electron mobility transistor (HEMT) is a commonly-used semiconductor device. In the process of manufacturing a compound semiconductor device for radio-frequency (RF), fabrication of a gate electrode is important, and processing of a T-shaped gate is pretty difficult. Currently, in the process of manufacturing a deep sub-micron compound semiconductor device, electron-beam lithography and multilayer resist (MLR) are generally used to fabricate a T-shaped gate. A T-shaped gate refers to a gate electrode that has a T-shaped cross section, so that a bottom surface of the T-shaped gate that is in contact with an epitaxial structure of the semiconductor device is narrow, thereby improving cutoff frequency of the semiconductor device. In addition, a top portion of the T-shaped gate is wide, which may reduce resistance of the T-shaped gate. In practice, in the lithography process adopting i-line ultraviolet (UV) light exposure, a gate electrode having a bottom surface that has a length (i.e., a gate length) not smaller than 0.35 micrometers may be fabricated. The electron-beam lithography process may be used to fabricate a gate electrode having a gate length smaller than 0.1 micrometers. However, because of equipment limitation, during the electron-beam lithography process, only point-by-point scanning can be performed, which leads to a relatively low processing efficiency.

Currently, due to limitation of steppers, it is difficult to further reduce a gate length of a T-shaped gate to meet actual need. Accordingly, there is room for improvement within the art.

### SUMMARY

Therefore, an object of the disclosure is to provide a semiconductor device and a method for preparing the same that can alleviate at least one of the drawbacks of the prior art.

According to one aspect of the disclosure, the semiconductor device includes an epitaxial structure, a first passivation layer, a second passivation layer and a gate structure. The first passivation layer is disposed on the epitaxial structure and has a through hole. The through hole extends from a top surface of the first passivation layer to a bottom surface of the first passivation layer. The first passivation layer has a side surface that borders the through hole and that is a curved surface. The second passivation layer is disposed in the through hole and covers the side surface of the first passivation layer. The gate structure passes through the through hole and is connected to the epitaxial structure.

According to another aspect of the disclosure, the semiconductor device includes an epitaxial structure, a first passivation layer, a second passivation layer and a gate structure. The first passivation layer is disposed on the epitaxial structure and has a through hole and a recess that spatially communicates with the through hole. The through hole extends from a top surface of the first passivation layer to a bottom surface of the first passivation layer, and the recess is spaced apart from the epitaxial structure. The second passivation layer is disposed in the recess of the first passivation layer. The gate structure passes through the through hole and is connected to the epitaxial structure. The first passivation layer has a side surface that borders the recess and that is a curved surface.

According to another aspect of the disclosure, a method for preparing a semiconductor device includes forming a first passivation layer on an epitaxial structure, forming a through hole and a recess that spatially communicates with the through hole in the first passivation layer, forming a second passivation layer, and forming a gate structure. The through hole extends from a top surface of the first passivation layer to a bottom surface of the first passivation layer. The recess is spaced apart from the epitaxial structure. The first passivation layer has a side surface that borders the recess and that is a curved surface. The second passivation layer is disposed in the recess and covers the side surface of the first passivation layer. The gate structure extends into the through hole and is connected to the epitaxial structure.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is sectional schematic view illustrating a first embodiment of a semiconductor device according to the disclosure.

FIG. 2 is an enlarged view of Section A in FIG. 1.

FIG. 3 is a sectional schematic view illustrating a second embodiment of a semiconductor device according to the disclosure.

FIG. 4 is an enlarged view of Section A in FIG. 3.

FIGS. 5 to 11 are schematic views illustrating a process of manufacturing the second embodiment.

FIG. 12 is a sectional schematic view illustrating a third embodiment of a semiconductor device according to the disclosure.

FIG. 13 is a sectional schematic view illustrating a fourth embodiment of a semiconductor device according to the disclosure.

FIG. 14 is a sectional schematic view illustrating a fifth embodiment of a semiconductor device according to the disclosure.

FIG. 15 is a sectional schematic view illustrating a sixth embodiment of a semiconductor device according to the disclosure.

FIG. 16 is a schematic perspective view of the second embodiment.

FIG. 17 is a sectional schematic view illustrating a modified gate structure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

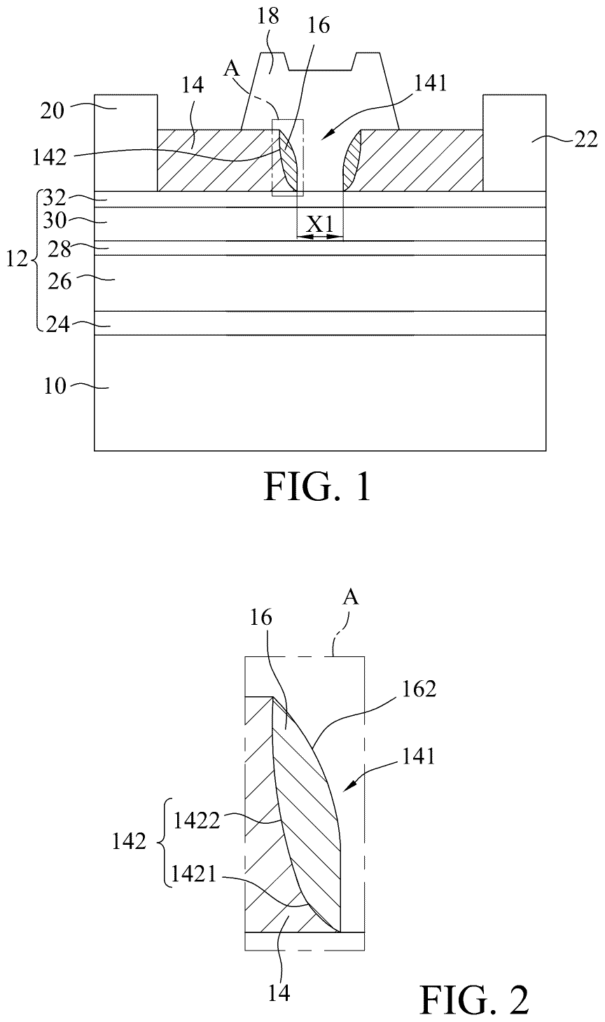

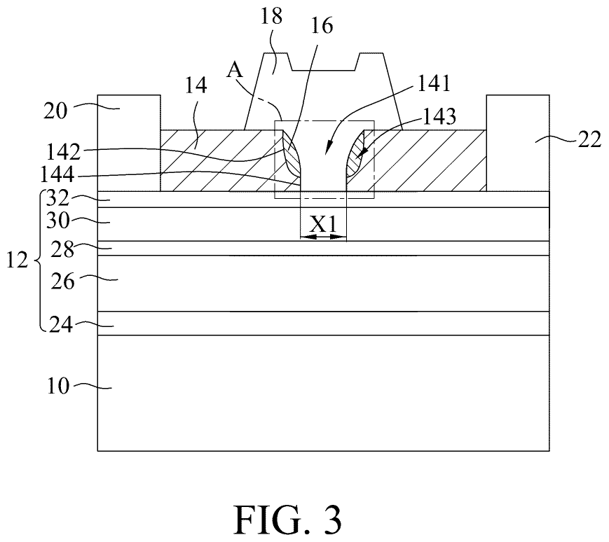

Referring to FIGS. 1 and 2, a first embodiment of a semiconductor device according to the disclosure can be adapted for a gallium arsenide (GaAs) high electron mobility transistor (HEMT) device, a GaN HEMT device, a GaAs pseudomorphic HEMT (pHEMT) device, a metal insulator semiconductor HEMT (MISHEMT) device, etc. The semiconductor device of the disclosure includes an epitaxial structure 12, a first passivation layer 14, a second passivation layer 16 and a gate structure 18. The epitaxial structure 12 may be disposed on a substrate 10. The substrate 10 may be a silicon substrate, a silicon carbide substrate, etc. The gate structure 18 may be made of a metal material, a TiN material, or other suitable materials. The epitaxial structure 12 includes group III-nitride heterojunction. In some embodiments, the epitaxial structure 12 includes a nucleation layer 24, a buffer layer 26, an interposing layer 28, a barrier layer 30 and a capping layer 32 that are sequentially stacked on the substrate 10. A material of the nucleation layer 24 may be aluminum nitride (AlN). A material of the buffer layer 26 may be gallium nitride (GaN). A material of the interposing layer 28 may be AlN. A material of the barrier layer 30 may be aluminum gallium nitride (AlGaN). A material of the capping layer 32 may be GaN. The barrier layer 30 has an Al content mole fraction ranging from 10% to 30% based on a total molar content of the barrier layer 30, and a thickness ranging from 10 nm to 30 nm. It is noted that some of the abovementioned structural layers of the epitaxial structure 12 can be selectively disposed, for example, the nucleation layer 24, the interposing layer 28 and the capping layer 32 may be omitted simultaneously or individually. That is to say, the buffer layer 26 and the barrier layer 30 cannot be omitted, while the nucleation layer 24, the interposing layer 28 and the capping layer 32 may be selectively omitted.

The semiconductor device further includes a source metal structure 20 and a drain metal structure 22. The source metal structure 20 and the drain metal structure 22 are disposed on the epitaxial structure 12 and are spaced apart from each other. The gate structure 18 is disposed between the source metal structure 20 and the drain metal structure 22.

The first passivation layer 14 is disposed on the epitaxial structure 12. The first passivation layer 14 is made of a material that is selected from the group consisting of silicon oxide, silicon nitride, silicon oxynitride and combinations thereof, and has a thickness ranging from 50 nm to 200 nm. In some embodiments, the first passivation layer 14 may include silicon dioxide (SiO₂). The first passivation layer 14 has a single-layered structure or a multi-layered structure. The first passivation layer 14 has a through hole 141, which extends from a top surface of the first passivation layer 14 to a bottom surface of the first passivation layer 14, in order to expose a portion of the epitaxial structure 12. The gate structure 18 passes through the through hole 141 and is connected to the epitaxial structure 12. A length (X1) of the epitaxial structure 12, which extends in a direction from the source metal structure 20 to the drain metal structure 22, which is parallel to a top surface of the epitaxial structure 12, and which is exposed from the through hole 141, is not smaller than 70 nm, i.e., a gate length of 70 nm of the semiconductor device can be achieved using a conventional stepper, details of which will be described in the following. In some embodiments, the length (X1) ranges from 70 nm to 250 nm. From a source to a drain of a semiconductor device, when currents pass, power loss unavoidably occurs; a gate length (i.e., a length of a gate structure that is in contact with an epitaxial structure of the semiconductor device in a direction from the source to the drain) determines an amount of the power loss. For example, the narrower the gate length, the lower the power loss. Therefore, when a semiconductor device in an apparatus (e.g., a smart phone) has a relatively narrow gate length, the device operating voltage and the power loss will be reduced accordingly, such that overheating due to the power loss may be alleviated. That is, by narrowing the gate length, cutoff frequency of the apparatus is improved, which allows the apparatus to be applied in a relatively higher frequency range.

The first passivation layer 14 has a side surface 142 that borders the through hole 141 and that is a curved surface. The side surface 142 is a surface that is not perpendicular to the top surface of the epitaxial structure 12 in a thickness direction from the first passivation layer 14 to the epitaxial structure 12, and may be a complete and continuous curved surface, a surface that includes a plurality of curved surfaces connecting to each other, a surface that includes a plurality of plane surfaces with different slopes connecting to each other, a surface that includes a plurality of curved surfaces and plane surfaces connecting to each other, etc. In the first embodiment, the side surface 142 includes two arc surfaces. By virtue of the configuration of the side surface 142, the semiconductor device can acquire a relatively smaller gate length when the stepper is used in the manufacturing process thereof, thus improving performance of the semiconductor device.

The side surface 142 includes a first arc surface 1421 and a second arc surface 1422. The first arc surface 1421 has two ends that are respectively connected to the second arc surface 1422 and the bottom surface of the first passivation layer 14, and the second arc surface 1422 has two ends that are respectively connected to the top surface of the first passivation layer 14 and the first arc surface 1421. The first arc surface 1421 has a cross-section in the thickness direction, and the cross-section of the first arc surface 1421 is an arc of a circle; the second arc surface 1422 has a cross-section in the thickness direction, and the cross-section of the second arc surface 1422 is an arc of another circle; radii of the two circles are different. That is, a radius of curvature of the first arc surface 1421 is different from a radius of curvature of the second arc surface 1422. The radius of curvature of the first arc surface 1421 ranges from 35 nm to 65 nm, and the radius of curvature of the second arc surface 1422 is greater than that of the first arc surface 1421. The second passivation layer 16 is disposed in the through hole 141 and covers the side surface 142 of the first passivation layer 14. The second passivation layer 16 has a side surface 162 that is opposite to the side surface 142 of the first passivation layer 14 and that is a convex surface protruded in a direction away from the side surface 142 of the first passivation layer 14. The side surface 142 of the first passivation layer 14 is a concave surface that is recessed in a direction away from the side surface 162 of the second passivation layer 16. That is to say, the side surface 142 of the first passivation layer 14 and the side surface 162 of the second passivation layer 16 respectively curve toward different directions. A radius of curvature of the side surface 162 of the second passivation layer 16 ranges from 60 nm to 150 nm.

Due to the configuration of the side surface 162 of the second passivation layer 16, it is beneficial to coverage of the gate structure 18 in the through hole 141, thereby decreasing metal voids due to poor coverage, and modulating gate electric field distribution to reduce gate edge field strength and optimize reliability. The side surface 142 is curved and thus has an increased surface area, which facilitates various active groups to diffuse on a thin film growth surface (i.e., an exposed surface of the first passivation layer 14) during vapor deposition, thereby increasing deposition film thickness uniformity of the second passivation layer 16 on the first passivation layer 14. In addition, because the radius of curvature of the second arc surface 1422 is greater than that of the first arc surface 1421, the gate structure 18 in the semiconductor device has a relatively smaller gate length.

The second passivation layer 16 is made of a material that is selected from the group consisting of silicon oxide, silicon nitride, silicon oxynitride and combinations thereof. The second passivation layer 16 has a single-layered structure or a multi-layered structure.

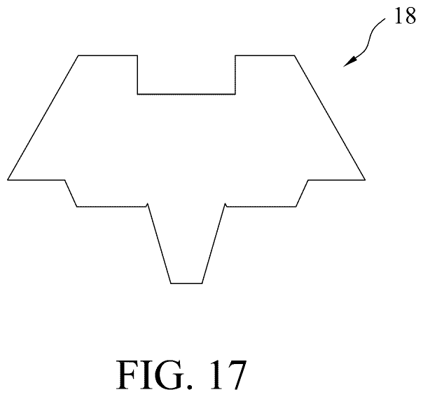

The gate structure 18 may be in contact with the first passivation layer 14 and the second passivation layer 16, and may be a T-shaped gate. In some embodiments, the gate structure 18 may be a T-shaped gate with two steps (see FIG. 17).

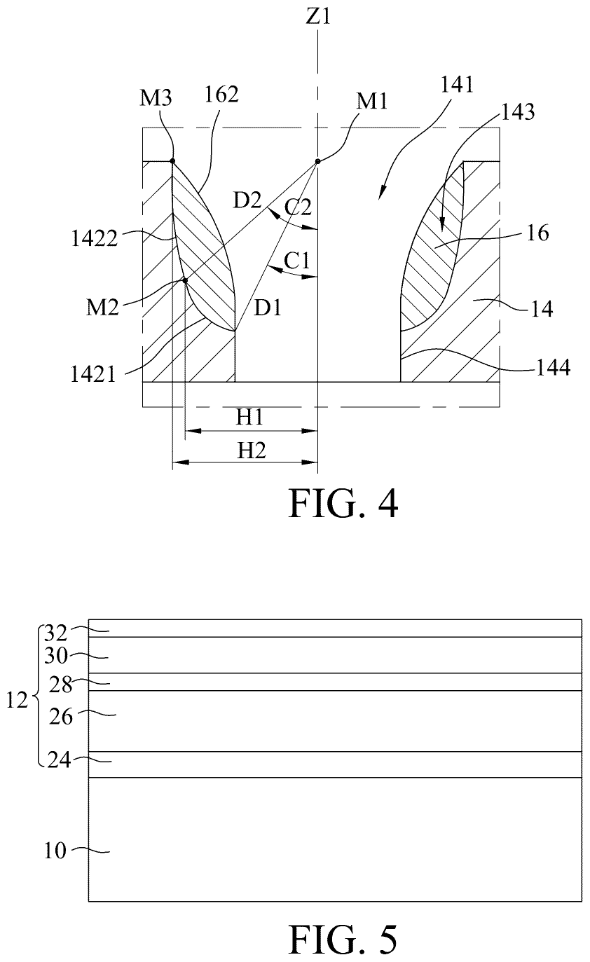

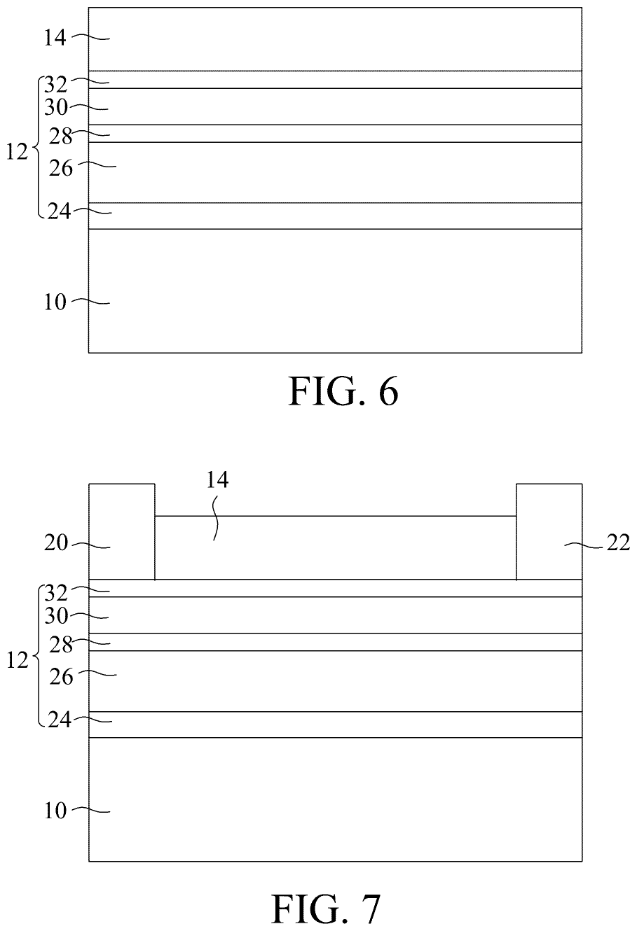

Referring to FIGS. 3 and 4, a second embodiment of the semiconductor device is shown, and includes the epitaxial structure 12, the first passivation layer 14 disposed on the epitaxial structure 12 and having the through hole 141, and the gate structure 18 extending into the through hole 141 and connected to the epitaxial structure 12. The through hole 141 extends from the top surface of the first passivation layer 14 to the bottom surface of the first passivation layer 14. Different from the first embodiment, in the second embodiment, the first passivation layer 14 further has a recess 143 that spatially communicates with the through hole 141. The recess 143 is spaced apart from the epitaxial structure 12 for a distance, which is greater than 0, and the second passivation layer 16 is disposed in the recess 143 of the first passivation layer 14. The first passivation layer 14 has a single-layered structure or a multi-layered structure. It is noted that in the second embodiment, the recess 143 is formed in a manner where a distance between a bottom end of the side surface 142 and the top surface of the epitaxial structure 12 is greater than 0.

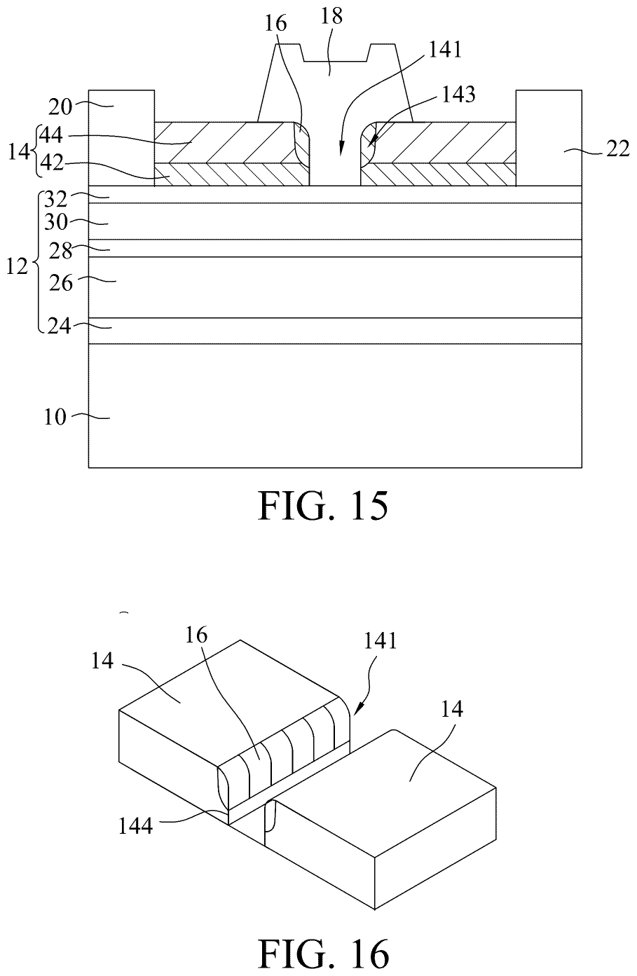

In order to reduce the gate length of the semiconductor device, the side surface 142 of the first passivation layer 14 that borders the recess 143 is a curved surface. The length (X1) of the epitaxial structure 12 exposed from the through hole 141 is not smaller than 70 nm, i.e., the gate length of the second embodiment is not smaller than 70 nm. In other embodiments, the length (X1) ranges from 70 nm to 250 nm. The first passivation layer 14 further has an inner surface 144 that extends from the side surface 142 and that borders the through hole 141 (see also FIG. 16). In some embodiments, the inner surface 144 may be perpendicular to the top surface of the epitaxial structure 12 in the thickness direction. In some embodiments, the second passivation layer 16 may be in contact with the epitaxial structure 12 (see FIG. 1), and in other embodiments, the second passivation layer 16 is spaced apart from the epitaxial structure 12 by a distance, i.e., an extending direction of the inner surface 144 in the thickness direction, and is located above the inner surface 144 so that the second passivation layer 16 is prevented from covering the inner surface 144 (see FIG. 3). An imaginary line (Z1) that passes through a center of the through hole 141 and that extends in the thickness direction perpendicular to the top surface of the epitaxial structure 12 and an imaginary plane that is coplanar with the top surface of the first passivation layer 14 intersect with each other at an intersection point (M1). A first included angle (C1) between a first line segment (D1) that connects a top end point of the inner surface 144 and the intersection point (M1) and the imaginary line (Z1) ranges from 10 degrees to 15 degrees.

In the second embodiment, the first passivation layer 14 has the first arc surface 1421 and the second arc surface 1422 that border the recess 143 in order to further reduce the gate length of the semiconductor device. That is to say, the side surface 142 includes the first arc surface 1421 and the second arc surface 1422. The first arc surface 1421 has two ends that are respectively connected to the second arc surface 1422 and the inner surface 144, and the second arc surface 1422 has two ends that are respectively connected to the top surface of the first passivation layer 14 and the first arc surface 1421. In a vertical cross section of the semiconductor device in the thickness direction, the first arc surface 1421 and the second arc surface 1422 interconnect with each other at an interconnect point (M2), and a second line segment (D2) that connects the intersection point (M1) and the interconnect point (M2) is inclined relative to the imaginary line (Z1) by a second included angle (C2). The second included angle (C2) ranges from 20 degrees to 33 degrees. In some embodiments, a first distance (H1) that is from the interconnect point (M2) to the imaginary line (Z1) is smaller than a second distance (H2) that is from a top end point (M3) of the second arc surface (1422) to the imaginary line (Z1). The first distance (H1) ranges from 90 nm to 100 nm, and the second distance (H2) ranges from 100 nm to 125 nm. In the second embodiment, the first passivation layer 14 has a thickness ranging from 50 nm to 200 nm and the recess 143 is spaced apart from the epitaxial structure 12 by a distance ranging from 10% to 20% of the thickness of the first passivation layer 14. If the distance between the recess 143 and the epitaxial structure 12 is too short, a relatively smaller amount of the first passivation layer 14 that is left for forming the recess 143 might be undesirably removed due to over-etching that results from drifting of an etching speed (e.g., 2%), thereby resulting in failure in formation of the recess 143 shown in FIGS. 3 and 4. Besides, the configuration of the recess 143 is to reduce the times of etchings that the epitaxial structure 12 is subjected to, and to decrease damages to the top surface of the epitaxial structure 12 while etching. Thus, such a small distance may undesirably lead to more damages to the top surface of the epitaxial structure 12 instead. On the other hand, if the distance between the recess 143 and the epitaxial structure 12 is too long, the thickness of the first passivation layer 14 left beneath the second passivation layer 16 is relatively thick (i.e., a total thickness of the first passivation layer 14 and the second passivation layer 16 required to be removed for forming the through hole 141 and the recess 143), which is not beneficial to forming of a smaller gate length.

In some embodiments, the first passivation layer 14 is made of a material of SiNₓ, and the second passivation layer 16 is made of a material of SiN_{y}, where y>x. Thus, a ratio of nitrogen to silicon of the second passivation layer 16 is greater than a ratio of nitrogen to silicon of the first passivation layer 14. The greater a ratio of nitrogen to silicon, the faster a speed of etching. The first passivation layer 14 including SiNₓ with a relatively higher density serves as a first layer that is in contact with the epitaxial structure 12, which has a better passivation effect to reduce negative effects such as leakage of electricity, etc. between layers. Moreover, the second passivation layer 16 including SiN_{y} with a relatively lower density is disposed in the recess 143, and is not directly in contact with the epitaxial structure 12. Therefore, it can improve an etching speed without affecting an interface state between SiN and the epitaxial structure 12, which is beneficial to shortening an etching time and further reducing the gate length. In addition, the second passivation layer 16 is not directly in contact with the epitaxial structure 12, so damages to the top surface of the epitaxial structure 12 resulting from multiple times of etching are reduced.

In some embodiments, the second passivation layer 16 has the side surface 162 that is a convex surface protruded in the direction away from the side surface 142 of the first passivation layer 14 and that is an arc surface (see FIG. 4). Compared to a right-angled surface or a concave surface, it is relatively gentle and can further benefit the coverage of the gate structure 18 in the through hole 141, thereby decreasing metal voids between the gate structure 18 and the first and second passivation layers 14, 16 due to poor coverage, and modulating gate electric field distribution to reduce gate edge field strength and optimize reliability of the semiconductor device.

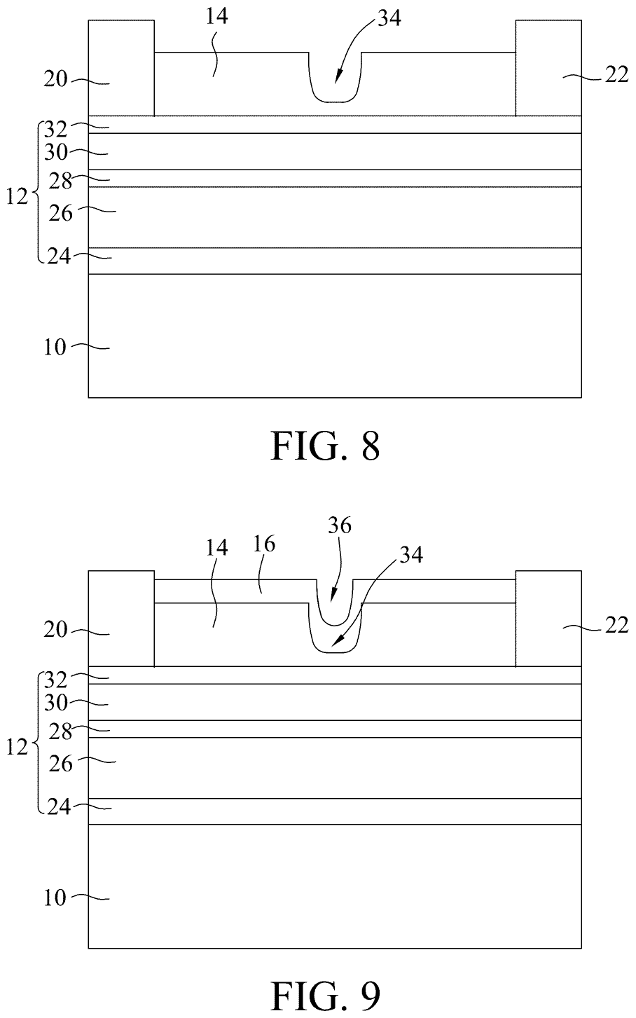

FIGS. 5 to 11 are schematic views illustrating a process of manufacturing the second embodiment in FIG. 3. A method for preparing a semiconductor device is as follows.

First, as shown in FIG. 5, the epitaxial structure 12 is formed on the substrate 10. In specific, by metal-organic chemical vapor deposition (MOCVD), the nucleation layer 24 containing AlN, the buffer layer 26 containing GaN, the interposing layer 28 containing AlN, the barrier layer 30 containing AlGaN and the capping layer 32 containing GaN are sequentially formed on the substrate 10. The barrier layer 30 has the Al content mole fraction ranging from 10% to 30% based on the total molar content of the barrier layer 30, and the thickness ranging from 10 nm to 30 nm.

Then, as shown in FIG. 6, the first passivation layer 14 is formed on the epitaxial structure 12 using plasma-enhanced chemical vapor deposition (PECVD) equipment under 200° C. to 400° C. at a gas atmosphere including SiH₄, NH₃, N₂, He, etc. The thickness of the first passivation layer 14 containing SiN ranges from 50 nm to 200 nm. After the deposition, annealing is performed using rapid thermal annealing (RTA) equipment under 400° C. to 600° C. for 0 second to 300 seconds at a nitrogen atmosphere.

Next, as shown in FIG. 7, a periphery of the first passivation layer 14 is removed. A metal layer is disposed on the epitaxial structure 12, and is connected to an outer surface of the first passivation layer 14, in order to prepare the source metal structure 20 and the drain metal structure 22. In specific, photolithography is performed using the stepper to generate a pattern of an electrode area. Then, an ohmic structure is formed using electron beam evaporation equipment, and the ohmic structure may be a structure stacked by Ti, Pt, Au, and Ti (i.e., a stack structure of Ti/Pt/Au/Ti). After evaporation, metal lift-off is performed to remove surplus metal; ohmic annealing is performed using rapid thermal annealing (RTA) equipment under 400° C. to 600° C. at a nitrogen atmosphere. Thus, the ohmic structure is alloyed and the source metal structure 20 and the drain metal structure 22 are obtained.

As shown in FIG. 8, a portion of the first passivation layer 14 is removed to form a first pit 34 (the recess 143 of the first passivation layer 14 is a portion of a remaining portion of the first pit 34). A distance between the bottom of the first pit 34 and the epitaxial structure 12 is greater than 0. In specific, a conventional i-line stepper is used to expose and form a gate pattern, and a length of the gate pattern in the direction from the source metal structure 20 to the drain metal structure 22 parallel to the top surface of the epitaxial structure 12 ranges from 160 nm to 180 nm. Inductively coupled plasma (ICP) is performed to etch the first passivation layer 14 to form the first pit 34 that is substantially arc shaped and that is a deep sub-micron gate recess. Then, photoresist stripping equipment is used to remove photoresist. That is to say, the first pit 34 is formed by photolithography.

As shown in FIG. 9, the second passivation layer 16 is formed on the first passivation layer 14 and is in the first pit 34. The second passivation layer 16 has the second pit 36 that corresponds in position to the first pit 34. In specific, the second passivation layer 16 containing SiN is formed using PECVD equipment under 200° C. to 400° C. at a gas atmosphere including SiH₄, NH₃, N₂, and He. The thickness of the second passivation layer 16 ranges from 5 nm to 200 nm. Since the first pit 34 of the first passivation layer 14 does not extend through the first passivation layer 14 to the epitaxial structure 12, it can reduce a size of the first pit 34, and thereby results in the second pit 36 of the second passivation layer 16 having a relatively smaller size. Therefore, a greater process window is provided, which leads to the gate length of the semiconductor device being smaller. Besides, it prevents the top surface of the epitaxial structure 12 from being damaged due to etching.

Referring to FIG. 10, the first passivation layer 14 and the second passivation layer 16 are dry etched (during the process, a top surface of the second passivation layer 16, side surfaces of the first passivation layer 14 and the second passivation layer 16 that respectively border the first pit 34 and the second pit 36, and bottoms of the first pit 34 and the second pit 36 are subjected to an ion bombard treatment (e.g., ICP process) and chemical reaction (by which SiN is removed) to form an arc shape until the portion of the epitaxial structure 12 under the first pit 34 is exposed. In specific, gas used in the ICP process includes CF 4 with a flow rate of 40 sccm to 200 sccm, and N₂ with a flow rate of 10 sccm to 50 sccm; an RF power of an upper electrode is 100 W to 400 W, and an RF power of a bottom electrode is 0 W to 20 W. The first passivation layer 14 and the second passivation layer 16 are etched to form the through hole 141 and the recess 143 in the first passivation layer 14. The recess 143 is spaced apart from the epitaxial structure 12 and spatially communicates with the through hole 141. The through hole 141 corresponds in position to the first pit 34 and extends from the top surface of the first passivation layer 14 to the bottom surface of the first passivation layer 14 so as to expose the portion of the epitaxial structure 12. The first passivation layer 14 has the side surface 142 that borders the recess 143 and that is a curved surface. The side surface 142 is a surface that is not perpendicular to the top surface of the epitaxial structure 12 in the thickness direction from the first passivation layer 14 to the epitaxial structure 12, and may be a complete and continuous curved surface, a surface that includes of a plurality of curved surfaces connecting to each other, a surface that is defined by a plurality of plane surfaces with different slopes connecting to each other, a surface that is defined by of a plurality of curved surfaces and plane surfaces connecting to each other, etc. The second passivation layer 16 is disposed in the recess 143 of the first passivation layer 14 and covers the side surface 142. The length (X1) of the portion of the epitaxial structure 12 exposed from the through hole 141 is not smaller than 70 nm. In addition, the first passivation layer 14 further has the inner surface 144 that extends from the side surface 142 and that borders the through hole 141. The side surface 142 includes the first arc surface 1421 and the second arc surface 1422. The first arc surface 1421 has the two ends that are respectively connected to the second arc surface 1422 and the inner surface 144, and the second arc surface 1422 has the two ends that are respectively connected to the top surface of the first passivation layer 14 and the first arc surface 1421. The radius of curvature of the first arc surface 1421 is different from the radius of curvature of the second arc surface 1422.

Finally, as shown in FIG. 11, the gate structure 18 is disposed on the first passivation layer 14 and the second passivation layer 16, and passes through the through hole 141 and is connected to the epitaxial structure 12.

The above is merely the method for manufacturing the second embodiment of the present disclosure, and the present disclosure is not limited thereto. Further, in the process for forming the first pit 34 in the first passivation layer 14, the first pit 34 is formed by etching through the first passivation layer 14, and then the first embodiment of the semiconductor device 1 can be manufactured.

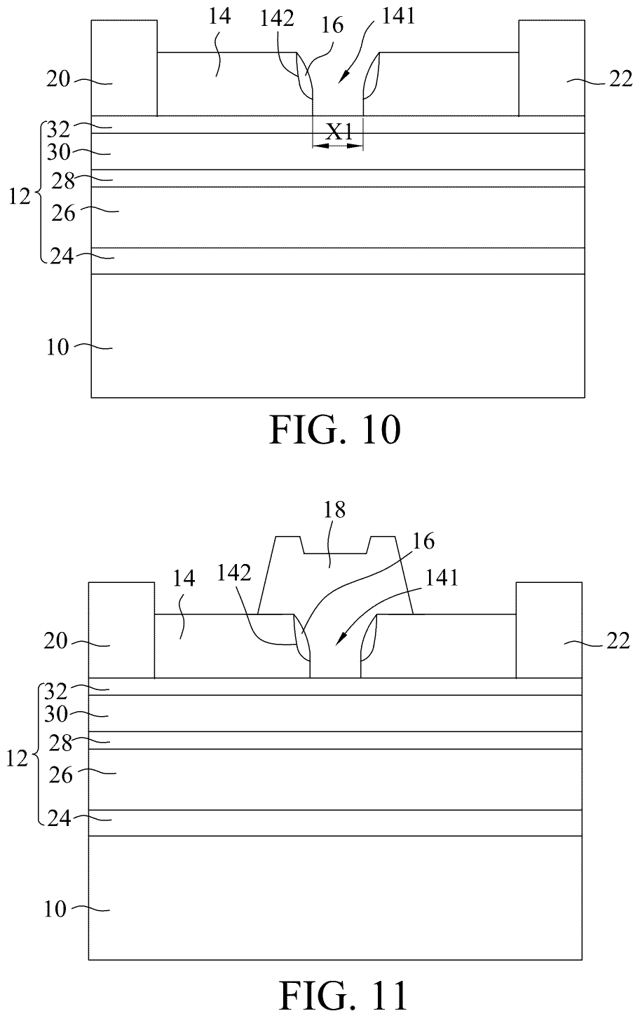

Referring to FIG. 12, a third embodiment of the semiconductor device is shown. Different from the first embodiment, in the third embodiment, the side surface 142 of the first passivation layer 14 is a complete curved surface, and is a convex surface, while the side surface 142 of the first embodiment is a concave surface.

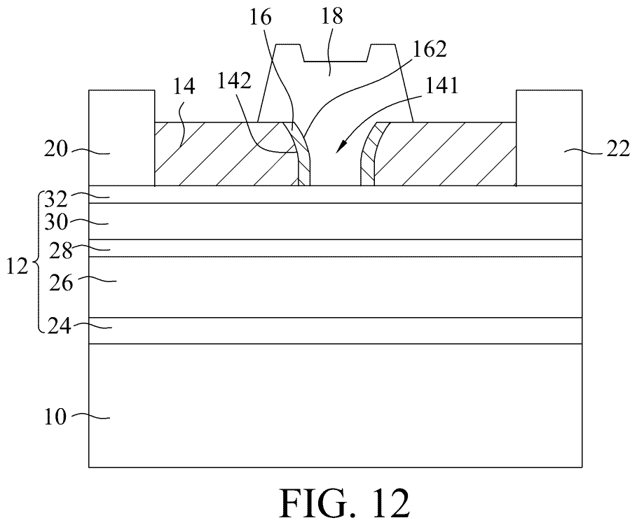

Referring to FIG. 13, a fourth embodiment of the disclosure is shown. Differences between the fourth embodiment and the second embodiment shown in FIG. 3 lie in that the top surface of the epitaxial structure 12 has a recessed portion 38 that is under the through hole 141. Cl-based inductively coupled plasma (ICP) or reactive-ion etching (RIE) may be used to form the recessed portion 38, and a depth of the recessed portion 38 along the thickness direction ranges from 1 nm to 3 nm. The recessed portion 38 can suppress the negative shift of the threshold voltage that results from gate dielectric, improve control of two dimensional electron gas (2DEG) in the channel by the gate structure 18 and enhance transconductance. By virtue of controlling the depth of the recessed portion 38 (e.g., between 1 nm to 3 nm), an interface state density between the first and second passivation layers 14, 16 and the epitaxial structure 12 can be reduced, and the current collapse effect can be weakened.

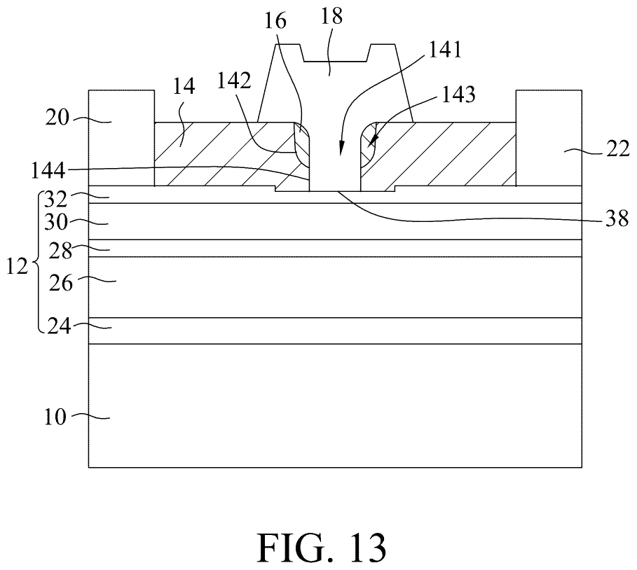

Referring to FIG. 14, a fifth embodiment of the disclosure is shown. Different from the second embodiment, in the fifth embodiment, a third passivation layer 40 covers the first passivation layer 14, the second passivation layer 16 and a portion of the epitaxial structure 12. That is, the third passivation layer 40 is disposed in the through hole 141, and the gate structure 18 is disposed on the third passivation layer 40 and is connected to the epitaxial structure 12 through the third passivation layer 40. A material of the third passivation layer 40 may be Si₃N₄, HfO₂, Al₂O₃, etc. The third passivation layer 40 is formed by atomic layer deposition (ALD), and has a thickness ranging from 3 nm to 10 nm. By virtue of the third passivation layer 40 serving as an insulating dielectric under the gate structure 18, a MISHEMT structure is formed, which in turn significantly reduces current leakage of the gate structure 18, increases a breakdown voltage and subthreshold swing of the semiconductor device, and improves linearity. At the same time, the third passivation layer 40 makes a surface of the semiconductor device stable, suppresses current collapse and improves reliability of the semiconductor device in the long run.

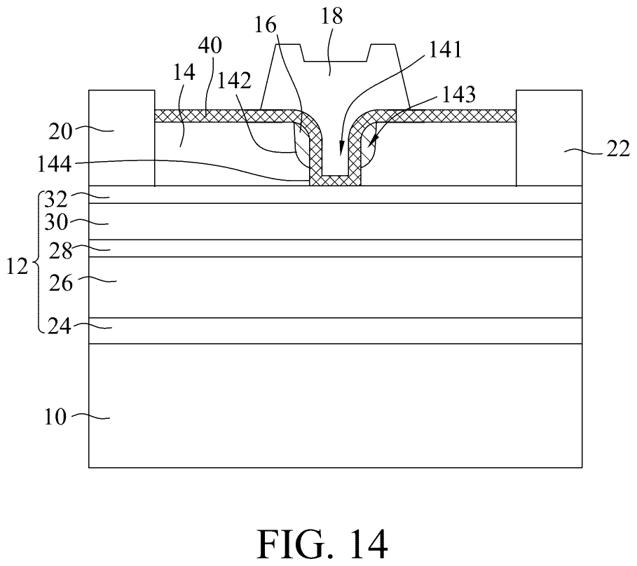

Referring to FIG. 15, a sixth embodiment of the disclosure is shown. Differences between the second embodiment shown in FIG. 3 and the sixth embodiment lie in that, in the sixth embodiment, the first passivation layer 14 has a multi-layered structure, and includes a first passivation sub-layer 42 and a second passivation sub-layer 44. The first passivation sub-layer 42 is disposed between the second passivation sub-layer 44 and the epitaxial structure 12. Quality of the first passivation sub-layer 42 is adjusted by using SiN as a material thereof, which has a relatively higher density (i.e., a density of the first passivation sub-layer 42 is greater than that of the second passivation sub-layer 44), so that an etching speed of the first passivation sub-layer 42 is slower than that of the second passivation sub-layer 44, which is beneficial to controlling an etching depth and improves controllability of on-through etching process. In addition, compared to the first passivation layer 14 having a single-layered structure, in the sixth embodiment, the first passivation sub-layer 42 is a thin layer, which can be used for improving passivation of the semiconductor device and for interface optimization, and the second passivation sub-layer 44 has the same structure as the first passivation layer 14 of the second embodiment. By the above arrangement of the first and second passivation sub-layers 42, 44, a density of surface state of the interface between the epitaxial structure 12 and the first passivation layer 14 may be changed to achieve an effect of suppressing current collapse, and the passivation of the semiconductor device is optimized without severely affecting the etching process (e.g., a speed of etching).

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor device, comprising:
an epitaxial structure;
a first passivation layer disposed on said epitaxial structure and having a through hole, said through hole extending from a top surface of said first passivation layer to a bottom surface of said first passivation layer, said first passivation layer having a side surface that borders said through hole and that is a curved surface;
a second passivation layer disposed in said through hole and covering said side surface of said first passivation layer; and
a gate structure passing through said through hole and being connected to said epitaxial structure.

2. The semiconductor device as claimed in claim 1, wherein said side surface includes a first arc surface and a second arc surface, said first arc surface having two ends that are respectively connected to said second arc surface and said bottom surface of said first passivation layer, said second arc surface having two ends that are respectively connected to said top surface of said first passivation layer and said first arc surface, a radius of curvature of said first arc surface being different from a radius of curvature of said second arc surface.

3. The semiconductor device as claimed in claim 2, wherein the radius of curvature of said first arc surface ranges from 35 nm to 65 nm, the radius of curvature of said second arc surface being greater than that of said first arc surface.

4. The semiconductor device as claimed in claim 1, wherein said second passivation layer has a side surface that is opposite to said side surface of said first passivation layer and that is a convex surface, said side surface of said first passivation layer being a concave surface, a radius of curvature of said side surface of said second passivation layer ranging from 60 nm to 150 nm.

5. The semiconductor device as claimed in claim 1, wherein
said first passivation layer is made of a material that is selected from the group consisting of silicon oxide, silicon nitride, silicon oxynitride and combinations thereof;
said second passivation layer is made of a material that is selected from the group consisting of silicon oxide, silicon nitride, silicon oxynitride and combinations thereof; and
a length of said epitaxial structure exposed from said through hole is not smaller than 70 nm.

6. The semiconductor device as claimed in claim 1, wherein
said first passivation layer has a thickness ranging from 50 nm to 200 nm; and
a length of said epitaxial structure exposed from said through hole is not greater than 250 nm.

7. A semiconductor device, comprising:
an epitaxial structure;
a first passivation layer disposed on said epitaxial structure and having a through hole and a recess that spatially communicates with said through hole, said through hole extending from a top surface of said first passivation layer to a bottom surface of said first passivation layer, said recess being spaced apart from said epitaxial structure;
a gate structure extending into said through hole and being connected to said epitaxial structure; and
a second passivation layer disposed in said recess of said first passivation layer;
wherein said first passivation layer has a side surface that borders said recess and that is a curved surface.

8. The semiconductor device as claimed in claim 7, wherein said first passivation layer has a single-layered structure or a multi-layered structure, and a length of said epitaxial structure exposed from said through hole is not smaller than 70 nm.

9. The semiconductor device as claimed in claim 7, wherein said first passivation layer further has an inner surface that extends from said side surface and that borders said through hole, an imaginary line that passes through a center of said through hole and an imaginary plane that is coplanar with said top surface of said first passivation layer intersecting with each other at an intersection point, a first included angle between a first line segment that connects a top end point of said inner surface and the intersection point and the imaginary line ranging from 10 degrees to 15 degrees.

10. The semiconductor device as claimed in claim 9, wherein said side surface includes a first arc surface and a second arc surface, said first arc surface having two ends that are respectively connected to said second arc surface and said inner surface, said second arc surface having two ends that are respectively connected to said top surface of said first passivation layer and said first arc surface, in a vertical cross section of said semiconductor device, said first arc surface and said second arc surface interconnecting with each other at an interconnect point, a second line segment that connects the intersection point and the interconnect point being inclined relative to the imaginary line by a second included angle, the second included angle ranging from 20 degrees to 33 degrees.

11. The semiconductor device as claimed in claim 10, wherein a first distance that is from the interconnect point to the imaginary line is shorter than a second distance that is from a top end point of said second arc surface to the imaginary line.

12. The semiconductor device as claimed in claim 11, wherein the first distance ranges from 90 nm to 100 nm, and the second distance ranges from 100 nm to 125 nm.

13. The semiconductor device as claimed in claim 7, wherein
said first passivation layer has a thickness ranging from 50 nm to 200 nm; and
a length of said epitaxial structure exposed from said through hole is not greater than 250 nm.

14. The semiconductor device as claimed in claim 7, wherein said recess is spaced apart from said epitaxial structure by a distance ranging from 10% to 20% of a thickness of said first passivation layer.

15. The semiconductor device as claimed in claim 7, wherein said semiconductor device further includes a substrate, said epitaxial structure being disposed on said substrate and including group III-nitride heterojunction.

16. The semiconductor device as claimed in claim 7, wherein said first passivation layer is made of a material of SiNₓ, and said second passivation layer is made of a material of SiN_{y}, where y>x.

17. The semiconductor device as claimed in claim 7, wherein said semiconductor device further includes a third passivation layer that covers said first passivation layer, said second passivation layer and a portion of said epitaxial structure, said gate structure being disposed on said third passivation layer.

18. A method for preparing a semiconductor device, comprising:
forming a first passivation layer on an epitaxial structure;
forming a through hole and a recess that spatially communicates with the through hole in the first passivation layer, the through hole extending from a top surface of the first passivation layer to a bottom surface of the first passivation layer, the recess being spaced apart from the epitaxial structure, the first passivation layer having a side surface that borders the recess and that is a curved surface;
forming a second passivation layer, the second passivation layer being disposed in the recess and covering the side surface of the first passivation layer; and
forming a gate structure that extends into the through hole and that is connected to the epitaxial structure.

19. The method as claimed in claim 18, wherein in the steps of forming the through hole and the recess in the first passivation layer and forming the second passivation layer,
a portion of the first passivation layer is removed to form a first pit, a distance between a bottom of the first pit and the epitaxial structure being greater than 0;
the second passivation layer is formed on the first passivation layer and is in the first pit, the second passivation layer having a second pit that corresponds in position to the first pit; and
the first passivation layer and the second passivation layer are dry etched to form the through hole and the recess in the first passivation layer, the through hole extending from the top surface of the first passivation layer to the bottom surface of the first passivation layer so as to expose a portion of the epitaxial structure, a length of the portion of the epitaxial structure exposed from the through hole being not smaller than 70 nm.

20. The method as claimed in claim 19, wherein the first passivation layer further has an inner surface that extends from the side surface and that borders the through hole, and the side surface includes a first arc surface and a second arc surface, the first arc surface having two ends that are respectively connected to the second arc surface and the inner surface, the second arc surface having two ends that are respectively connected to the top surface of the first passivation layer and the first arc surface, a radius of curvature of the first arc surface being different from a radius of curvature of the second arc surface.
